(19) United States
(12) Patent Application Publication
(10) Pub. No.: US 2003/0036217 A1
(43) Pub. Date: Feb. 20, 2003

(54) Microcavity semiconductor laser coupled to a waveguide

(75) Inventors: Fred V. Richard, Scottsdale, AZ (US); Paige M. Holm, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/985,757

(22) Filed: Nov. 6, 2001

Related U.S. Application Data
(63) Continuation-in-part of application No. 09/930,243, filed on Aug. 16, 2001.

(51) Int. Cl. H01S 5/00

(52) U.S. Cl. 438/98; 257/98

(57) ABSTRACT

High quality epitaxial layers of monocrystalline materials can be grown overlying monocrystalline substrates such as large silicon wafers by forming a compliant substrate for growing the monocrystalline layers. One way to achieve the formation of a compliant substrate includes first growing an accommodating buffer layer on a silicon wafer. The accommodating buffer layer is a layer of monocrystalline oxide spaced apart from the silicon wafer by an amorphous interface layer of silicon oxide. The amorphous interface layer dissipates strain and permits the growth of a high quality monocrystalline oxide accommodating buffer layer. The foregoing is utilized for a microcavity semiconductor laser coupled to a waveguide.

### RELATED PATENT APPLICATION

The present patent application is a Continuation-In-Part of “Microcavity Semiconductor Laser” naming F. Richards and P. Holm inventors, filed on Aug. 16, 2001 and assigned U.S. application Ser. No. 09/930,243, which is assigned to the assignee of the present invention.

### FIELD OF THE INVENTION

This invention relates generally to semiconductor structures and devices and to a method for their fabrication, and more specifically to semiconductor structures and devices and to the use of semiconductor structures, devices, and integrated circuits that include a monocrystalline material layer comprised of semiconductor material, compound semiconductor material, and/or other types of material such as metals and non-metals, and even more specifically to a semiconductor structure having a microcavity semiconductor laser coupled to a waveguide. The microcavity semiconductor laser and/or the waveguide is formed at least partially of a monocrystalline material layer, which is comprised of a semiconductor material, compound semiconductor material, and/or other types of material such as metals and non-metals.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material. Furthermore, if a thin film of high quality monocrystalline material could be realized beginning with a bulk wafer such as a silicon wafer, a semiconductor structure having a microcavity semiconductor laser coupled to a waveguide could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure that can be utilized in the formation of a microcavity semiconductor laser coupled to a waveguide. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film the same crystal orientation as an underlying substrate that can be utilized in the formation of a microcavity semiconductor laser coupled to a waveguide. This monocrystalline material layer may be comprised of a semiconductor material, a compound semiconductor material, and other types of material such as metals and non-metals.

A need also exists for lasers of higher efficiency, smaller size, and lower cost to facilitate their use in wide bandwidth data multiplexing applications, such as optical communication networks.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 21-23 illustrate schematically, in cross-section, the formation of yet another embodiment of a device structure in accordance with the invention.

FIG. 24 illustrates a perspective view of a semiconductor structure 134 that includes a microcavity semiconductor laser in accordance with an embodiment of the present invention;

FIG. 25 illustrates a top view of a microcavity semiconductor ring laser in accordance with an embodiment of the present invention;

FIG. 26 illustrates a top view of a microcavity semiconductor disk laser in accordance with an embodiment of the present invention;

FIG. 27 illustrates a top view of a microcavity semiconductor ring laser that is distorted in accordance with an embodiment of the present invention;

FIG. 28 illustrates a top view of a microcavity semiconductor disk laser that is distorted in accordance with an embodiment of the present invention;

FIG. 29 illustrates schematically, in cross-section, the microcavity semiconductor laser of FIG. 24 taken along lines 29-29;

FIG. 30 illustrates a top view of a microcavity semiconductor laser and a output waveguide optically coupled to the microcavity semiconductor laser in accordance with an embodiment of the present invention;

FIG. 31 illustrates schematically, in cross-section, the output waveguide of FIG. 20 in accordance with the an embodiment of the present invention;

FIG. 32 illustrates a top view of a microcavity semiconductor laser and multiple output waveguides optically coupled to the microcavity semiconductor laser in accordance with an embodiment of the present invention;

FIG. 33 illustrates a top view of a microcavity semiconductor laser and multiple input waveguides and an output waveguide coupled to the microcavity semiconductor laser in accordance with an embodiment of the present invention;

FIG. 34 illustrates schematically a laser in accordance with another embodiment of the present invention;

FIG. 35 illustrates a top view of a semiconductor laser system in accordance with an embodiment of the present invention;

FIG. 36 illustrates schematically, in cross-section, a microcavity semiconductor laser of the semiconductor laser system of FIG. 35 in accordance with the an embodiment of the present invention;

FIG. 37 illustrates a top view of a microcavity semiconductor laser and multiple output waveguides overlying the microcavity semiconductor laser in accordance with an embodiment of the present invention; and

FIG. 38 illustrates a top view of a microcavity semiconductor laser and multiple input waveguides overlying the microcavity semiconductor laser in accordance with an embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide, and other perovskite oxide materials. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds, Group IV and VI elements (IV-VI semiconductor compounds), mixed IV-VI compounds, Group IV element (Group IV semiconductors), and mixed Group IV compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), silicon (Si), germanium (Ge), silicon germanium (SiGe), silicon germanium carbide (SiGeC), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging form from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

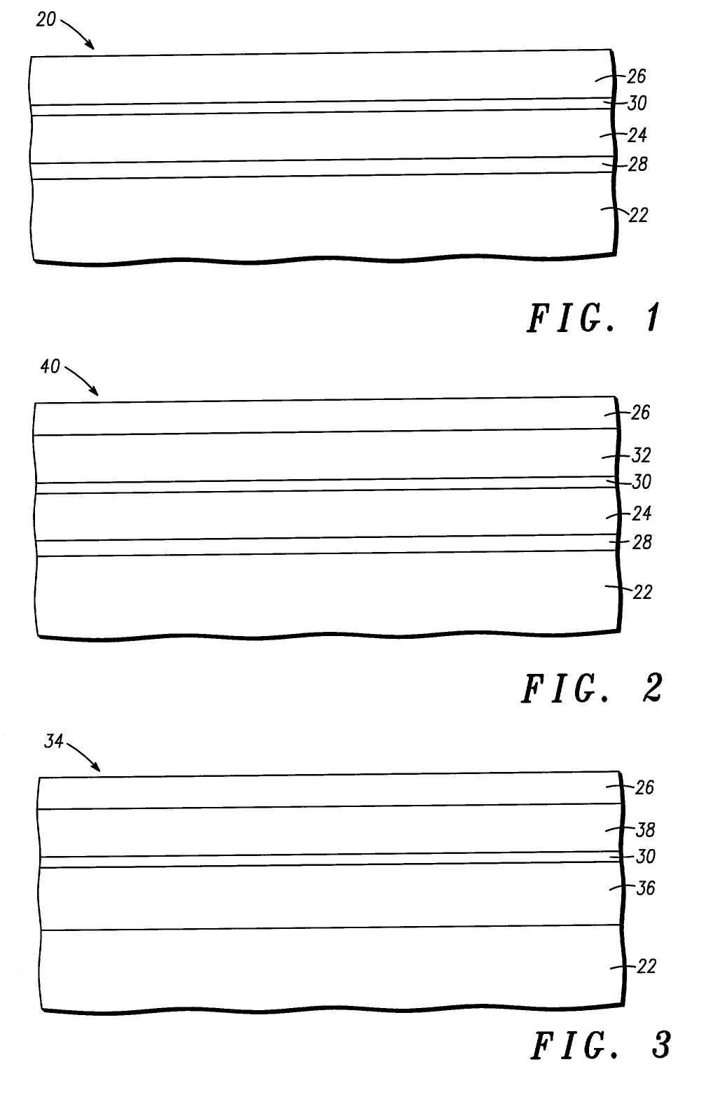

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then may then be optionally exposed to an anneal process to convert at least a portion of the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming at least a portion of a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 10.5-10 monolayers of Ti—As, Ti—O—As, Ti—O—Ga, Sr—O—As, Sr—Ga—O, or Sr—Al—O. By way of a preferred example, 10.5-2 monolayers of Ti—As or Sr—Ga—OTi—O—As have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 4 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is about 0.5-1 monolayers of one of a material M—N and a material M—O—N, wherein M is selected from at least one of Zr, Hf, Ti, Sr, and Ba and N is selected from at least one of As, P, Ga, Al, and In. Alternatively, the template may comprise 10.5-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 10.5-2 monolayers of one of these materials. By way of an example, for a barium zirconate accommodating buffer layer, the surface is terminated with 0.51-2 monolayers of zirconium followed by deposition of 0.51-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-153-10 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 0.51-10 monolayers of zinc-oxygen (Zn—O) followed by 0.51-2 monolayers of an excess of zinc followed by the selenidation of zinc on the surface. Alternatively, a template can be, for example, 0.51-10 monolayers of strontium-sulfur (Sr—S) followed by the ZnSeSZnSSe.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The superlattice period can have a thickness of about 2-15 nm, preferably, 2-10 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one 0.5-2 monolayers can be used as a nucleating site for the subsequent growth of the monocrystalline material layer which in this example is a compound semiconductor material. The formation of the oxide layer is capped with either a 0.5-1 monolayer of strontium or a 0.5-1 monolayer of titanium to act as a nucleating site for the subsequent deposition of the monocrystalline germanium. The monolayer layer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiO_{X} and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 1 nm to about 100 nm, preferably about 21-10 nm, and more preferably about 5-63-5 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer nm to about 100 500 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

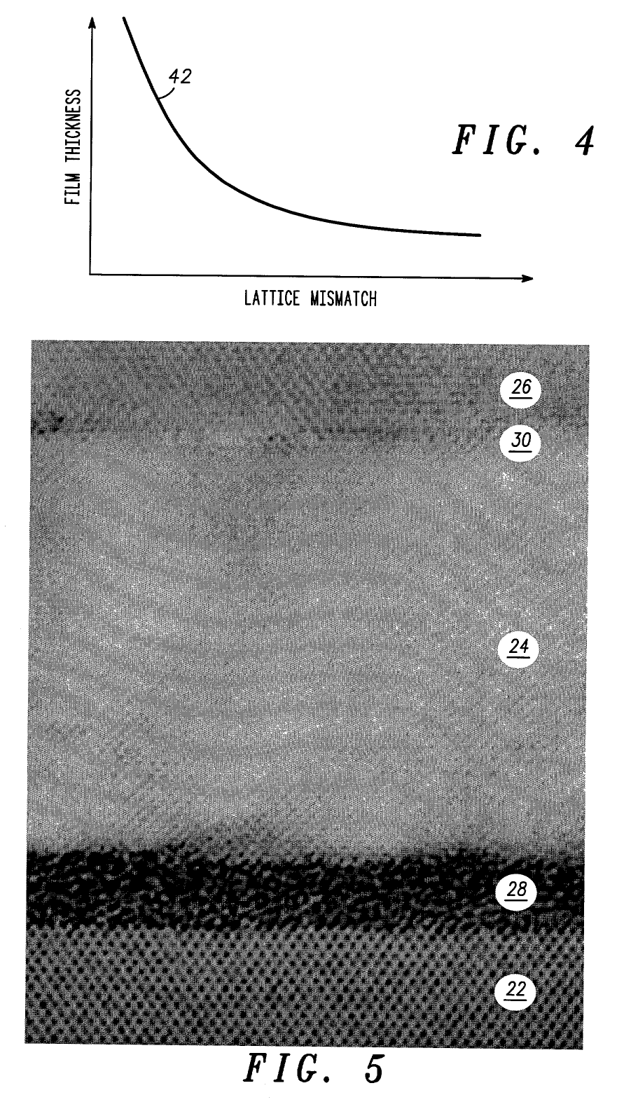

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4 about 6° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer (preferably 1-3 monolayers) of strontium, barium, a combination of strontium and barium, or other alkali alkaline earth metals or combinations of alkali alkaline earth metals in an MBE apparatus. In the case where strontium is used, the substrate is then heated to a temperature of about 850750 above 720° C. to cause the strontium to react with the native silicon oxide layer. The strontium serves to reduce the silicon oxide to leave a silicon oxide-free surface. The resultant surface, which may exhibit exhibits an ordered 2×1 structure, includes strontium, oxygen, and silicon. If an ordered (2×1) structure has not been achieved at this stage of the process, the structure may be exposed to additional strontium until an ordered (2×1) structure is obtained. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali alkaline earth metal oxide, such as strontium oxide, strontium barium oxide, or barium oxide, onto the substrate surface by MBE at a low temperature and by subsequently heating the structure to a temperature of about 850750 above 720° C. At this temperature a solid state reaction takes place between the strontium oxide and the native silicon oxide causing the reduction of the native silicon oxide and leaving an ordered 2×1 structure on the substrate surface with strontium, oxygen, and silicon remaining on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C., preferably 350-450° C., and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric stoichiometric strontium titanate at a growth rate of about 0.1-0.8 nm per minute, preferably 0.3-0.5 nm per minute. After initiating growth of the strontium titanate, the partial pressure of oxygen is increased above the initial minimum value. The stoichiometry of the titanium can be controlled during growth by monitoring REED patterns and adjusting the titanium flux. The overpressure of oxygen causes the growth of an amorphous silicon oxide layer at the interface between the underlying substrate and the growing strontium titanate layer. This step may be applied either during or after the growth of the SrTi layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 10.5-2 monolayers of titanium, 0.51-2 monolayers of titanium-oxygen or with 0.51-2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, a Sr—H—Ga bond, a Ti—H—Ga bonb, or a Ti—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

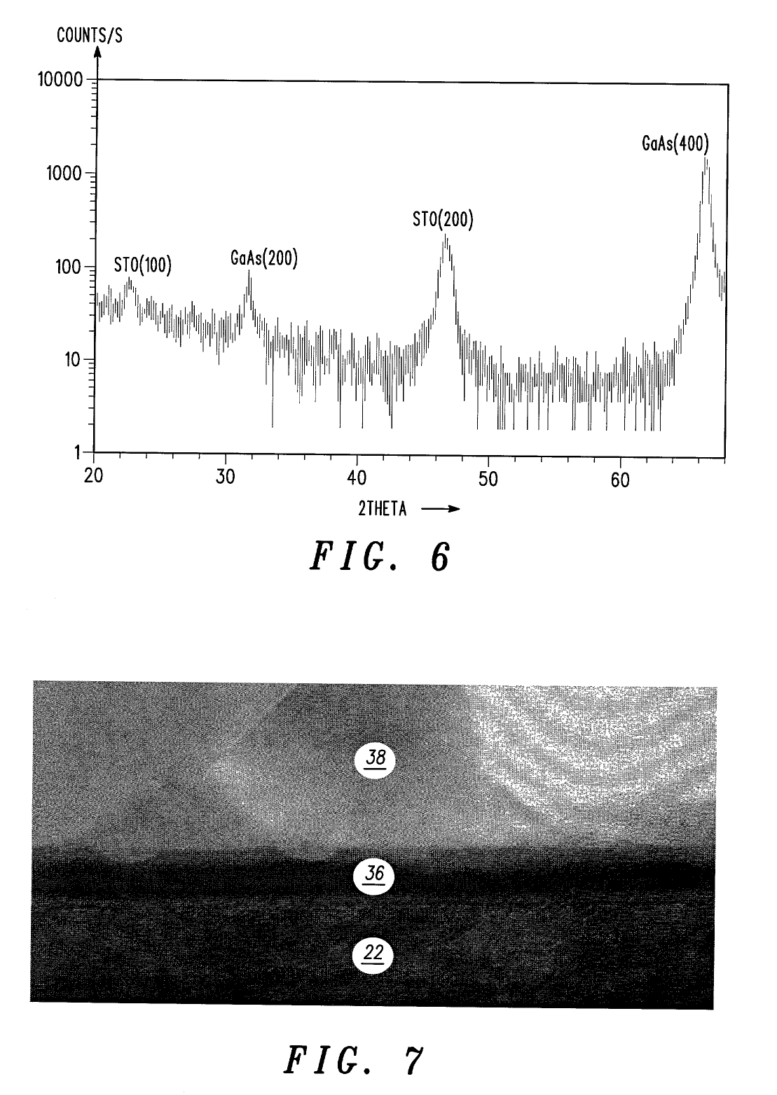

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 20 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

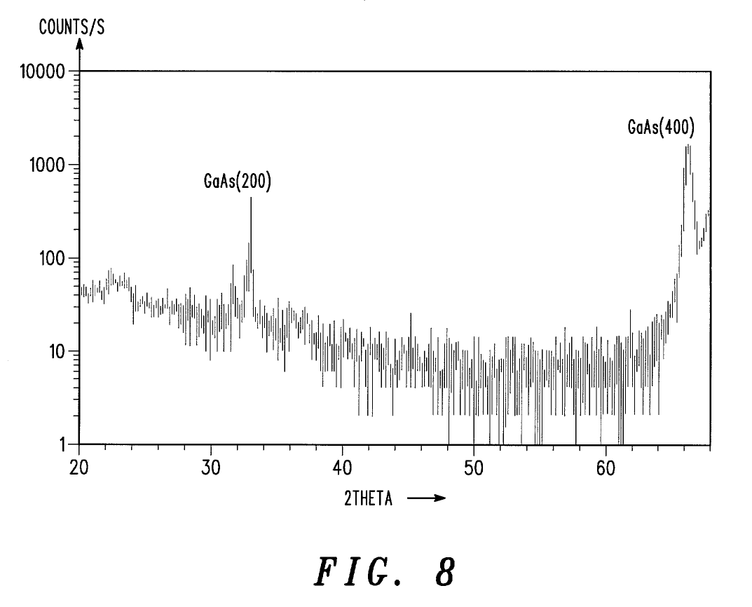

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V, and II-VI, and IV-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of 0.5-5.0 one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

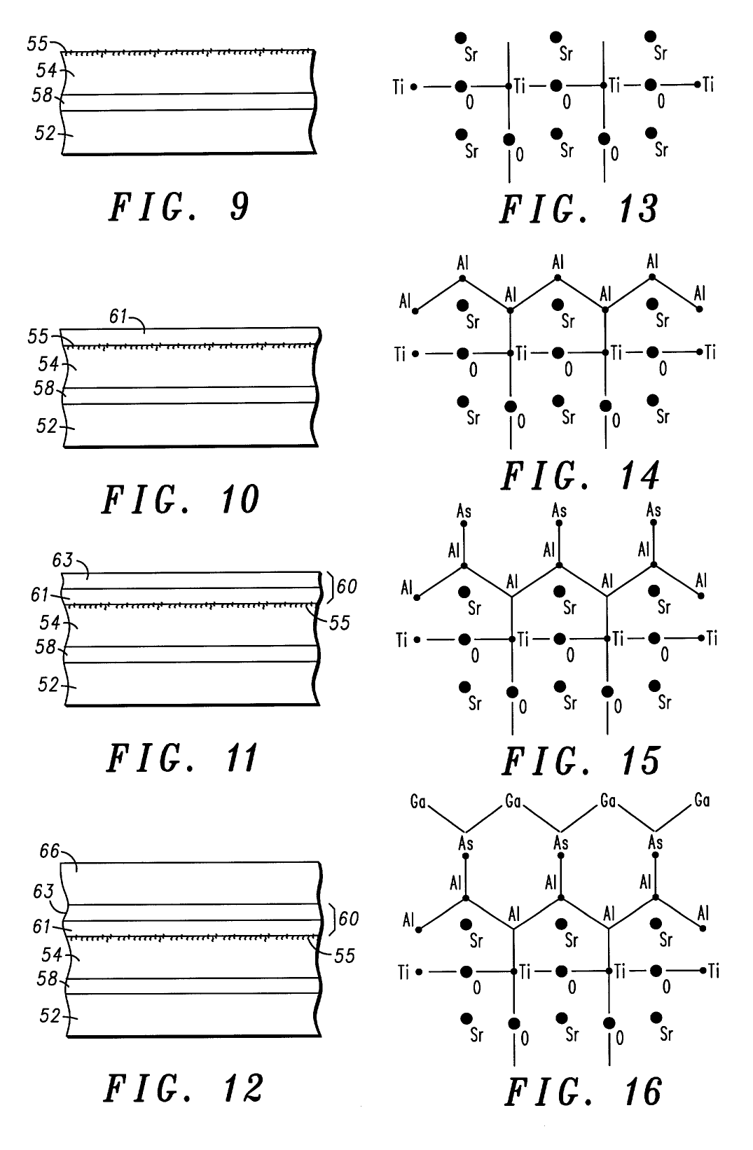

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms 100 nm where the two-dimensional (2D) and three-dimensional (3D) growth shifts because of the surface energies involved. In order to maintain a true layer by layer growth (Frank Van der Merwe growth), the following relationship must be satisfied:

δ_{STO}>(δ_{INT}+δ_{GaAs})

where the surface energy of the monocrystalline oxide layer 54 must be greater than the surface energy of the amorphous interface layer 58 between the accommodating buffer layer 54 and the GaAs layer 66 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

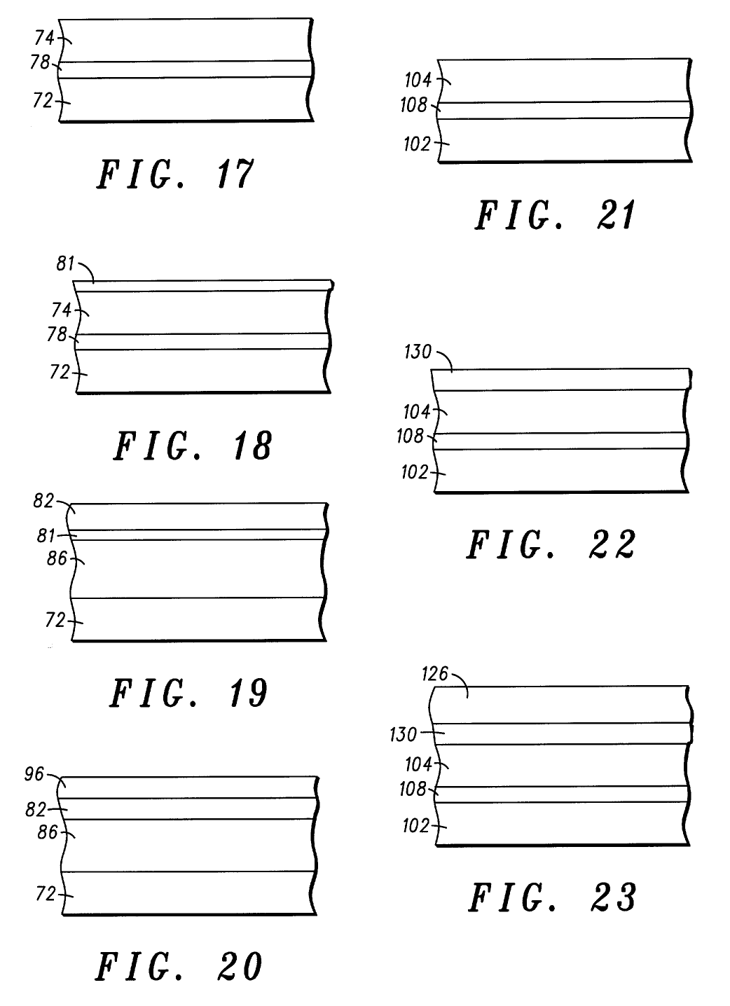

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few tens of nanometers hundred Angstroms but preferably with a thickness of about 50 Angstroms 5 nm. Monocrystalline oxide layer 74 preferably has a thickness of about 20 to 100 Angstroms 2 to 10 nm.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semicondcutor semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosizedamorphized to form a silicate layer which adsorbs the strain between the layers. MoroeverMoreover, unlike past use of a SiC substrate, this embodiment of the invention is not limited by wafer size which is usually less than 2 inches 50 mm in diameter for prior art SiC substrates.

The monolithic integration of nitride containing semiconductor compounds containing group III-V nitrides and silicon devices can be used for high temperature and high power RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Bi, Ga, In, and Sb such as and, for example, SrAlSr₂, (MgCaYb)Ga₂, (Ca, Sr, Eu, Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

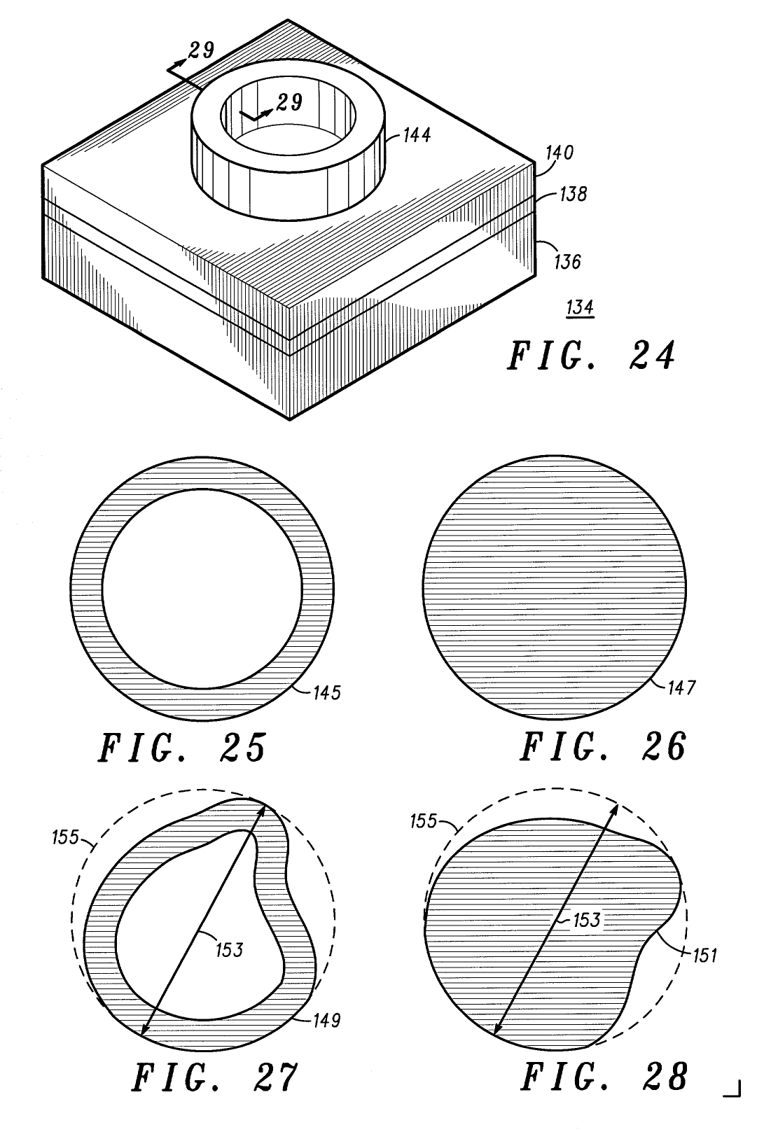

FIG. 24 illustrates a perspective view of a semiconductor structure 134 in accordance with an embodiment of the present invention. The semiconductor structure 134 is comprised of a monocrystalline silicon substrate 136, an amorphous oxide material 138 overlying the monocrystalline silicon substrate 136, and a monocrystalline perovskite oxide material 140 overlying the amorphous oxide material 138. The semiconductor structure 134 is also comprised of a monocrystalline compound semiconductor material as subsequently described in this detailed description of the drawings that is at least partially overlying the monocrystalline perovskite oxide material 140 and a microcavity semiconductor laser 144 formed at least partly from said monocrystalline compound semiconductor material. The microcavity semiconductor laser 144 is formed into an arcuate shape, linear shape and combinations thereof and preferably configured to have an elliptical cross-sectional periphery or substantially elliptical cross-sectional periphery (e.g., a circular or substantially circular cross-sectional periphery) in the form of a microcavity semiconductor ring laser 145 as illustrated in a top view shown in FIG. 25 or a microcavity semiconductor disk laser 147 illustrated in a top view shown in FIG. 26. However, the microcavity semiconductor laser 144 can have a periphery other than the substantially elliptical cross-sectional periphery and the microcavity semiconductor laser 144 can be a distorted or non-symmetrical ring or disk in accordance with the present invention, such as the distorted ring 149 illustrated in a top view shown in FIG. 27 and the distorted disk 151 illustrated in a top view shown in FIG. 28, with the effective diameter of the distorted ring 149 and the distorted disk 151 generally the diameter 153 of the ellipse (e.g., circle) 155 with the smallest diameter that can contain the entire areas of the distorted disk 151 or the distorted ring 149.

Continuing with reference to FIG. 24, the monocrystalline silicon substrate 136, amorphous oxide material 138, monocrystalline perovskite oxide material 140 and monocrystalline compound semiconductor material of the semiconductor structure 134 correspond to the monocrystalline substrate 22, amorphous intermediate layer 28, accommodating buffer layer 24 and monocrystalline material layer 26, respectively, previously described with reference to FIGS. 1-3 and other corresponding descriptions and figures of this detailed description of the drawings. In addition, the semiconductor structure 134 is preferably fabricated in accordance with the processes previously described in this detailed description of the drawings. Furthermore, the semiconductor structure 134 can be comprised of other layers that are fabricated in accordance with the processes previously described in this detailed description of the drawings. For example, in addition to the monocrystalline silicon substrate 136, amorphous oxide material 138, monocrystalline perovskite oxide material 140, a template layer 30, an additional buffer layer 32 and/or an amorphous layer 36 previously described with reference to FIGS. 1-3 and other corresponding description and figures of this detailed description of the drawings can be included in the semiconductor structure 134 in accordance with the present invention.

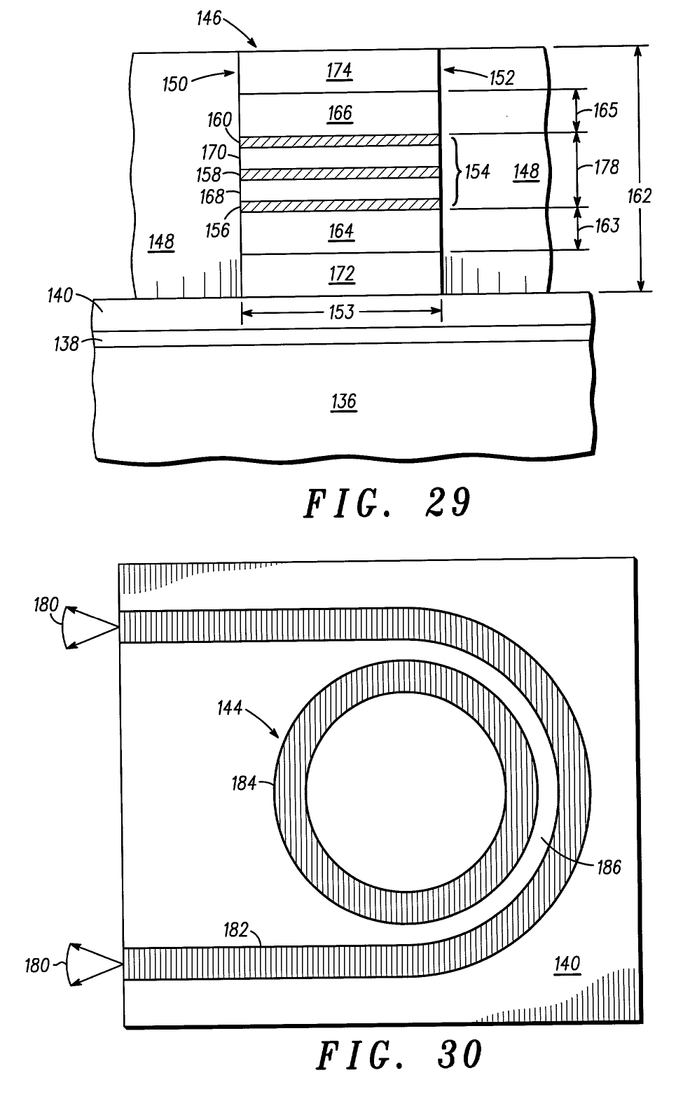

Referring to FIG. 29, a cross-sectional view of the microcavity semiconductor laser 144 illustrated in FIG. 24 is shown. The microcavity semiconductor laser 144 is formed at least partly from the monocrystalline compound semiconductor material overlying the monocrystalline perovskite oxide material 140 comprises an active lasing medium 146 in which photons can be generated that are capable of circulating about a periphery of the active lasing medium 146. The active lasing medium 146 supports optical modes in the form of whispering gallery modes, which are resonant modes having fields/wavelengths that are compatible with the radial dimensions of the microcavity semiconductor laser and well known in the art. Generally, photons generated in the active lasing medium 146 circulate around the periphery of the microcavity semiconductor laser and as the photons circulate around the periphery of the microcavity semiconductor laser, stimulated emission generates additional photons to form a lasing field. (See “Whispering-Gallery Mode Microdisk Lasers,” McCall et al., Appl. Phys. Lett. 60, (3), Jan. 20, 1992, pp. 289-291, and “Directional Light Coupling from Microdisk Lasers,” Levi et al., Appl. Phys. Lett. 62 (6), Feb. 8, 1993, pp. 561-563, and “Threshold Characteristics of Semiconductor Microdisk Lasers,” Appl. Phys. Lett. 63, (10), Sep. 6, 1993, pp. 1310-1312, R. E. Slusher. et al., and “Directional Light Coupling from Microdisk Lasers,” Appl. Phys. Lett. 62 (6), Feb. 8, 1993, pp. 561 563, A. F. Levi et al., and “Room-Temperature Lasing Action in In _{0.51} Ga _{0.49} P/In _{0.2} Ga._{0.8} As Microcylinder Laser Diodes,” Appl. Phys. Lett. 62 (17) , Apr. 26, 1993, pp. 2021-2023, A. F. Levi et al., and “Spontaneous Emission from Excitions in Thin Dielectric Layers,” Optics Letters, vol. 18, No. 11, 1 Jun. 1, 1993, pp. 909-911, S. T. Ho, et al., and “Estimation of the Spontaneous Emission Factor for Microdisk Lasers via the Approximation of Whispering Gallery Modes,” J. Appl. Phys. 75(7), 1 Apr. 1, 1994, pp. 3302-2207, Chin et al., and “Spontaneous Emission from Excitions in Cylindrical Dielectric Waveguides and the Spontaneous-Emission Factor of Microcavity Ring Lasers,” Opt. Soc. Am. vol. 10, No. 2, February 1993, “1.5 UM InGaAs/InAlGaAs Quantum Well Microdisk Lasers,” IEEE Photo. Tech. Ltr. vol. 5, No. 12, December 1993, pp. 1353 1355, D. Y. Chu et al., and Photonic-Wire Laser, Phy. Rev. Let., vol. 75, No. 14, Oct. 2, 1995, pp. 2678-2681, J. P. Zhang et al., and “Double-Disk Structure for Output Coupling in Microdisk Lasers,” Appl. Phys, Lett. 65 (25), Dec. 19, 1994, pp. 3167-3169, D. Y. Chu et al.) As can be appreciated by one of ordinary skill in the art, any number of microcavity semiconductor lasers having any number of configurations can be formed at least partly from the monocrystalline semiconductor material in addition to the microcavity semiconductor lasers described in this detailed description of the drawings to provide the stimulated emission, which generates the additional photons to form a lasing field. (See U.S. Pat. No. 5,790,583, issued to Seng-Tiong Ho on Aug. 4, 1998, U.S. Pat. No. 5,825,799, issued to Ho et al. on Oct. 20, 1998 and U.S. Pat. No. 5,926,496, issued to Ho et al. on Jul. 20, 1999.)

In order to provide the microcavity semiconductor laser that generates the additional photons to form the lasing field, the active lasing medium 146 of the microcavity semiconductor laser preferably comprises a relatively high refractive index medium that is surrounded by a relatively low refractive index medium 148. More specifically, the active lasing medium 146 of the relatively high refractive index medium is surrounded by the relatively low refractive index medium 148 on a first lateral side 150 and a second lateral side 152 that define the width 155 of the active lasing medium 146 such that photons are confined in a direction perpendicular to the direction of propagation. The strong confinement forms a strong confining potential well for photons, which affects the emission properties of the optically active, excitable medium of the active lasing medium 146, and can be used to significantly increase the percentage of emission into one particular mode of interest.

For example, the relative high refractive index medium can have a refractive index greater than approximately 2.5 and more preferably greater than approximately 3.0, whereas the relatively low refractive index mediums preferably can have a refractive index less than approximately 2.0 and more preferably less than approximately 1.6 and even more preferably less than approximately 1.5 and greater than approximately 1.0 or equal to approximately 1.0. According to a preferred embodiment of the present invention, the ratio of the refractive indices of the relatively high refractive index medium to the relatively low refractive index medium (i.e., ratio=relatively high refractive index medium/ relatively low refractive index medium) is greater than approximately 1.3. The relatively high refractive index medium can be any number of the monocrystalline compound semiconductor materials previously discussed in this detailed description of the drawings, including gallium arsenide (GaAs) and indium phosphide (InP) and the relatively low refractive index medium 148 can be any number of mediums including air, acrylic, epoxy, silicon dioxide (SiO₂), aluminum oxide, silicon nitride, spin-on glass, polymers with low absorption at the emission wavelength, photo resist, poly-methyl metacrorate, and polyimide. As previously described in this detailed description of the drawings, the relatively low refractive index medium 148 surrounding the first lateral side 150 and the second lateral side 152 serves to spatially confine photons in directions perpendicular to their circumferential propagation direction in the active lasing medium 146.

The active lasing medium 146 of the relatively high refractive index medium comprises an active layer 154 that is an optically active and excitable medium, which can give rise to radiation or absorption of electromagnetic field energy, and in particular gain or luminescence, when pumped or optically and/or electrically excited using techniques well known in the art. The active layer 154 preferably comprises at least one quantum well, quantum wire or quantum dot layer 156 and preferably multiple quantum wells, quantum wires or quantum dot layer layers (158, 160) having major sides parallel to one another and minor sides that are defined by the thickness of the quantum well layer (156, 158, 160). The active layer 154 is preferably located around the midpoint of the thickness 162 of the active lasing medium 146 and can comprise any number of quantum well materials, such as In_{0.53}Ga_{0.47}As. The active layer 154 can be excited by suitable means such as optically (e.g. by a pumping laser providing pulsed light of appropriate duty cycle) or electrically (e.g. by electrical current pulses of appropriate duty cycle comprising injection current pumping through a p-n diode junction) as is well known in the art.

A first guiding layer 164 and a second guiding layer 166 are disposed proximate the major sides of the active layer 154, which also have minor sides defined by the thickness 163 of the of the first guiding layer 164 and the thickness 165 of the second guiding layer 166. In addition, a barrier layer (168, 170) is disposed between the quantum well layers (156, 158, 160) of the active layer 154. The barrier layer (168, 170) can comprise any number of suitable passive guiding or barrier material as well known in the art, such as In_{0.84} Gao_{0.16} As_{0.67} P_{0.33}.

The active layer 154 is also disposed between a first cladding layer 172 overlying the monocrystalline perovskite oxide material 140 and a second cladding layer 174 overlying the second guiding layer 166, which have relatively high refractive indices as compared to the relatively low refractive index medium 148. More specifically, the first cladding layer 172 is disposed between the first guiding layer 164 and the monocrystalline perovskite oxide material 140 and the second cladding layer 174 is disposed over the second guiding layer 166. The first cladding layer 172 and the second cladding layer 174 can comprise indium phosphide (InP) having a refractive index of about 3.1. The refractive index of the first cladding layer 172 and the second cladding layer 174 is less than the refractive index of the first guiding layer 164, active layer 154 and second guiding layer 166.

The thickness 178 of the active layer 154 and the width 155 of the active lasing medium 146 that comprises the first cladding layer 172 overlying the monocrystalline perovskite oxide material 140, the first guiding layer 164 overlying the first cladding layer 172, the active layer 154 overlying the first guiding layer 164, the second guiding layer 166 overlying the active laser 154 and the second cladding layer 174 overlying the second guiding layer 166 are selected to provide particular wavelength ranges. For example, operation of the microcavity semiconductor laser at approximately a 1.1 micron to 1.6 micron wavelength range employs a width 155 that is less than or equal to about 0.4 micron and a thickness 178 of the active layer 154 that is less than or equal to about 0.3 micron with the width 155 and the thickness 178 of the active layer 154 preferably greater than about 0.1 micron. As another example, operation of the microcavity semiconductor laser at approximately a 0.2 micron to 0.7 micron wavelength range employs a width 155 that is less than or equal to about 0.1 micron or smaller and a thickness 178 of the active layer 154 that is less than or equal to about 0.1 micron with both the width 155 and the thickness 178 of the active layer 154 greater than about 0.02 micron. As yet another example, operation of the microcavity semiconductor laser at approximately a 0.7 micron to 1.1 microns wavelength range employs a width 155 that is less than or equal to about 0.25 micron and a thickness 178 of the active layer 154 that is less than or equal to about 0.2 micron with both the width 155 and the thickness 178 of the active layer 154 greater than about 0.06 micron. As yet still another example, operation of the microcavity semiconductor laser at approximately a 1.1 micron and 1.6 micron wavelength range employs a width 155 that is less than or equal to about 2.0 microns and a thickness 178 of the active layer 154 that is less than or equal to about 1.5 microns with the width 155 and the thickness 178 of the active layer 154 that is greater than about 0.1 micron. However, these examples for selection of a wavelength range with the width 155 and the thickness 178 of the active layer 154 are merely illustrative.

The lasing threshold of the microcavity semiconductor laser is achieved when the round trip optical gain of the electromagnetic field mode propagating in the active lasing medium due to the excited active medium exceeds the round trip optical loss. The round trip loss can be due to absorption and scattering by impurities or defects as well as roughness on the sidewalls of the microcavity semiconductor laser. It can also be due to photons leaking out to the output-coupled waveguide as will be subsequently described in this detailed description of the drawings. The pumping power needed to achieve the lasing threshold is partially used to cause inversion in the active layer 154 of the active lasing medium 146 at which the active layer 154 will become transparent and begin to contribute to the optical gain. This is generally known in the art as the transparency pumping power. The transparency pumping power is partially used to achieve additional gain above the transparency point so as to overcome the round trip optical loss. This is generally known in the art as the additional-gain pumping power. As can be appreciated by one of ordinary skill in the art, due to the high Q and the low loss nature of the active lasing medium, the additional-gain pumping power may be a relatively small part of the total threshold pumping power. Therefore, the threshold pumping power is primarily utilized for transparency pumping power and the transparency pumping power is preferably proportional to the total material volume of the active lasing medium 146. The threshold pumping power can be reduced with a reduced thickness 162 of the active lasing medium 146 and/or by reducing the area of the active layer 154. Hence, the threshold pumping power may be reduced by having the active layer 154 present only along a small section of the entire length of the active lasing medium 146 that forms the microcavity semiconductor laser waveguide that forms the cavity.

To reduce side-wall scattering loss, it is generally preferable to have the first lateral side 150 and the second lateral side 152 of the active lasing medium 146 fabricated with substantially smooth surfaces having roughness less than one tenth of the free-space wavelength divided by the relatively high refractive index medium of the active lasing medium 146. The power loss due to sidewall scattering loss is also dependent on the refractive index difference of the relatively high refractive index medium (N-core) of the active lasing medium 146 and relatively low refractive index medium 148 (N-low) surrounding the active lasing medium 146, or specifically directly proportional to (N_{core}²-N_{low}²)². Thus, reducing the refractive index difference between the relatively high refractive index medium of the active lasing medium 146 and the relatively low refractive index medium 148 surrounding the active lasing medium 146 can reduce the scattering loss. The desirability of the smooth surfaces for the first lateral side 150 and the second lateral side 152 can be relaxed for highly curved arcuate segments where the radius of the ellipse is small. Furthermore, it may actually be desirable to have the first lateral side 150 fabricated with rough surfaces to enforce lasing in the lowest-order guided mode.

Referring to FIG. 30, optical coupling of the microcavity semiconductor laser 144 to an output 180 can be provided with an output waveguide 182 overlying the monocrystalline perovskite oxide material 140 that is proximate a portion of the periphery 184 of the microcavity semiconductor laser 144 in a manner that achieves resonant photon tunneling. The output waveguide 182 is spaced apart from the periphery 184 by a gap region 186 of low refractive index material, such as air or other substances previously discussed in this detailed description of the drawings. The optical coupling involves a section of the microcavity semiconductor laser 144 and a section of the output waveguide 182 in which the photons in the active lasing medium are propagating in parallel. The refractive index of the gap region 186 is less than the refractive indices of the material of the output waveguide 182 and the active lasing medium forming the microcavity semiconductor laser 144. The gap region 186 is typically less than approximately 10 optical wavelengths and greater than approximately 0.02 optical wavelengths. The amount of coupling or energy transfer between the output waveguide 182 and the microcavity semiconductor laser 144 increases with the decreasing size of the gap region 186 and/or also increases with the coupling length, where the coupling length is the length for which the output waveguide 182 proximates the microcavity semiconductor laser 144.

The vertical structure of the output waveguide 182 is preferably similar, more preferably substantially the same and most preferably the same as the vertical structure of the active lasing medium 146 as shown in FIG. 29. Therefore, the vertical structure of the output waveguide 182 preferably comprises a first cladding layer 172 overlying the monocrystalline perovskite oxide material 140, a first guiding layer 164 overlying the first cladding layer 172, an active layer 154 overlying the first guiding layer 164, a second guiding layer 166 overlying the active layer 154 and a second cladding layer 174 overlying the second guiding layer 166 as illustrated in the cross-sectional view of FIG. 29. With the vertical structure of the output waveguide 182 as illustrated in the cross-sectional view of FIG. 29, the output waveguide 182 is preferably excited by optical or electrical pumping to avoid absorption of light by the unexcited active medium in the output waveguide. However, to avoid excitation of the output waveguide 182 by optical or electrical pumping the output waveguide 182, the vertical structure of the output waveguide 182 can have substantially the same and most preferably the same vertical structure as the active lasing medium 146 as shown in FIG. 29 without the active materials as illustrated in FIG. 31.

More specifically and with reference to FIG. 31, the output waveguide 182 can comprise the first cladding layer 172 overlying the monocrystalline perovskite oxide material 140, a first guiding layer 164 overlying the first cladding layer 172, a second guiding layer 166 overlying the first guiding layer 164 and a second cladding layer 174 overlying the second guiding layer 166. The output waveguide 182 can also have active materials (i.e., active layer 154 materials of FIG. 29) present at sections of the output waveguide 182 and the sections having the active materials can be electrically and/or optically pumped to achieve population inversion, giving rise to optical gain for light propagating in the output waveguide 182. This configuration of the output waveguide 182 with active materials at sections of the output waveguide 182 can be used to provide further amplification of optical power from the microcavity semiconductor laser, thereby providing an increase of the net optical power in the waveguide as compared to the configuration of the output waveguide 182 without active materials at sections of the output waveguide 182. However, the configuration of the output waveguide 182 with the active materials at sections of the output waveguide 182 can remain unexcited and function as a detector.

For example, the output waveguide 182 can function as a detector with the absorption of light, which will cause excitation of the active layer in proportion to the light power that is absorbed by the active materials at sections of the output waveguide 182. The excitation can be detected with any number of devices such as a closed electric circuit. The current of the closed electric circuit provides an indication of the optical power in the output waveguide 182. The active layer sections can also function as a modulator by modulating the pumping power, leading to a modulation of optical absorption or gain of the active medium section and hence the optical power through the section. Irrespective of the configuration of the output waveguide 182, the output waveguide 182 can be formed at a level on the monocrystalline perovskite oxide material that is compatible with an integrated optical circuit integrated circuit that can be formed on the monocrystalline perovskite oxide material 140 using any number of techniques and configurations well known in the art or on or within another layer of the semiconductor structure so as to provide light output signals to the optical circuit.

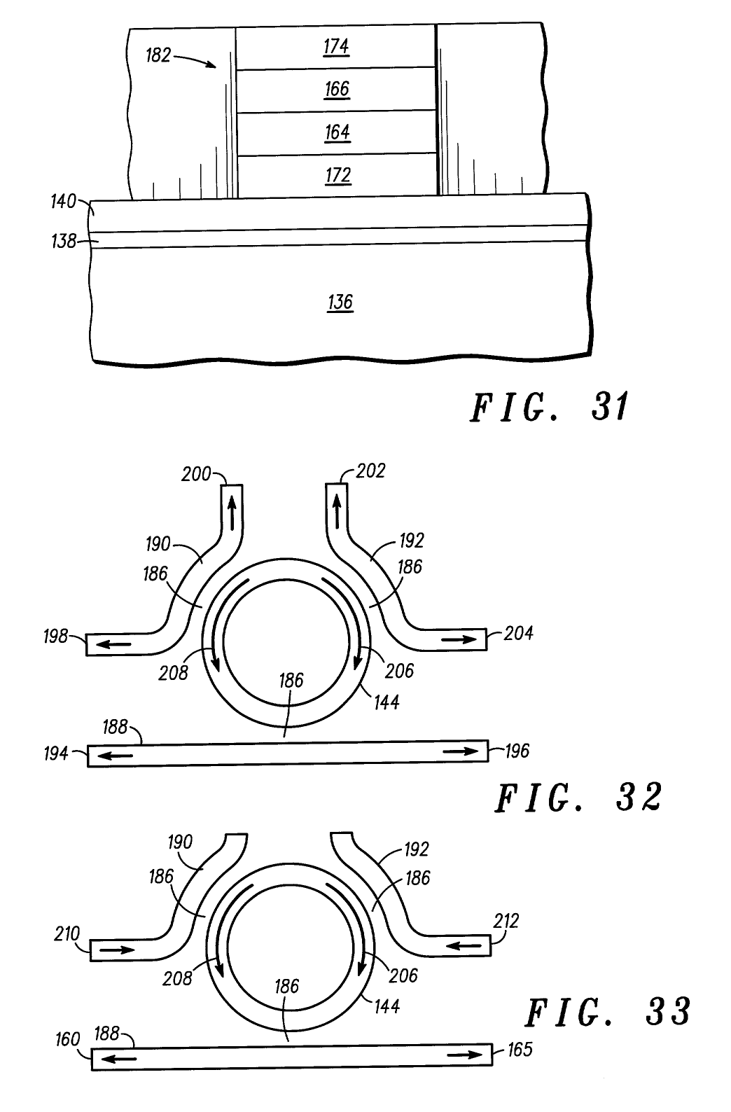

Referring to FIG. 32, the microcavity semiconductor laser 144 can be also be coupled to multiple output waveguides such as a first output waveguide 188, a second output waveguide 190 and a third output waveguide 192 at different segments of the microcavity semiconductor laser 144 thereby providing multiple output ports such as the first output port 194, second output port 196, third output port 198, fourth output port 200, fifth output port 202 and sixth output port 204. As can be appreciated by one of ordinary skill in the art, the light in the microcavity semiconductor laser 144 can be divided into multiple beams such as a first beam and a second beam with the first beam propagating in a first direction 206 (e.g., a clockwise direction) and the second beam propagating in a second direction 208 (e.g., a counterclockwise direction). The first beam, second beam or the first beam and the second beam can be brought above the lasing threshold via external pumping.

Referring to FIG. 33, one or more of the output waveguides (188, 190, 192) can also be configured to couple light from another light source or a second microcavity semiconductor laser (not shown) into the microcavity semiconductor laser 144, thereby forming multiple input ports such as the first input port 210 and second input port 212. The input ports (210, 212) can be used to introduce light in the form of pulses or continuous wave beams into the microcavity semiconductor laser 144, which can affect the properties of light output from the microcavity semiconductor laser 144. For example, the amplitudes, phases, frequencies, pulse duration, and polarization of the light output from the output ports (160, 165) can depend on the amplitudes, phases, frequencies, pulse duration, and polarization of the light input into one or more of the input ports (210, 212). The dependence can be different depending on the excitation level or population inversion in the microcavity semiconductor laser 144, or on whether the input beams in the microcavity semiconductor laser are brought above or below the lasing thresholds. As can be appreciated by one of ordinary skill in the art, such an input-output dependence can be used for processing signals or information coded in the properties of the input light beams, and can be a useful device for application to optical communications, optical interconnects, optical sensing, optical signal processing, and optical computing. As can also be appreciated by one of ordinary skill in the art, the presence of both input and output ports allows two or more microcavity semiconductor lasers to be connected by connecting the output port(s) of one microcavity semiconductor laser to the input port(s) of another microcavity semiconductor laser. As can be further appreciated by one of ordinary skill in the art, numerous microcavity semiconductor laser configurations can be provided in accordance with the present invention and numerous output coupling configurations can be provided in accordance with the present invention.

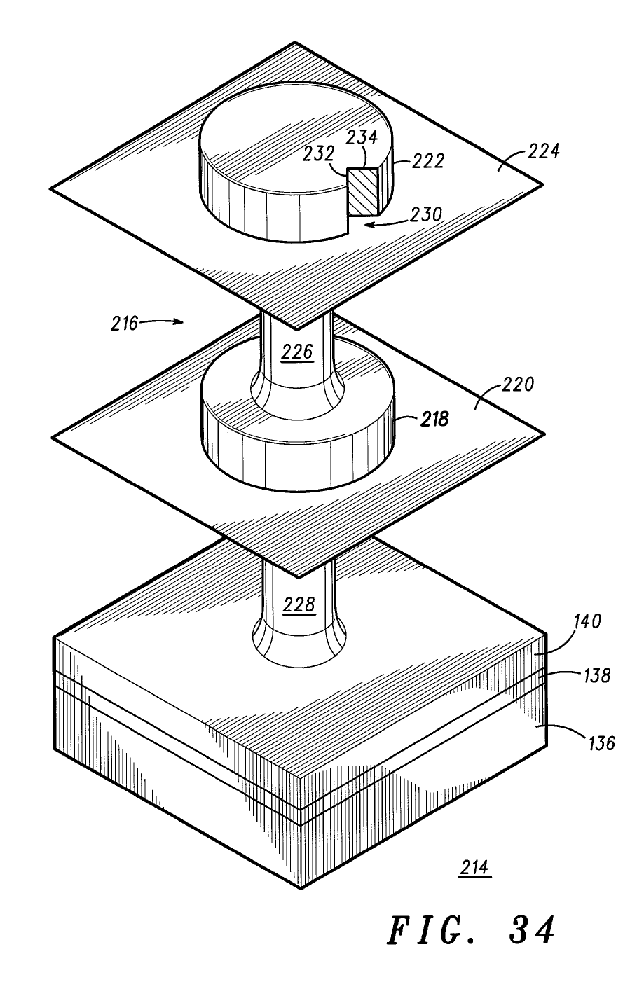

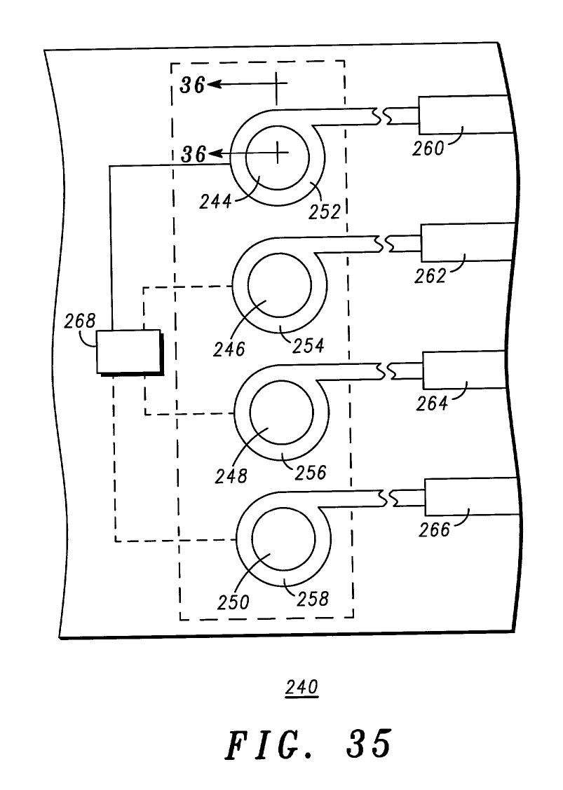

Referring to FIG. 34, another semiconductor structure 214 is illustrated in accordance with the present invention. The semiconductor structure 214 comprises a monocrystalline silicon substrate 136, an amorphous oxide material 138 overlying the monocrystalline silicon substrate 136, a monocrystalline perovskite oxide material 140 overlying the amorphous oxide material 138, a monocrystalline compound semiconductor material (not shown) overlying the monocrystalline perovskite oxide material 140 as described with reference to FIG. 24. In addition, a laser 216 is at least partly formed from the monocrystalline compound semiconductor material overlying the monocrystalline perovskite oxide material 140. The laser 216 comprises a lasing disk 218 in a first plane 220 with a substantially elliptical cross-sectional periphery and a guiding disk 222 with a substantially elliptical cross-sectional periphery spaced apart from the lasing disk 218 disposed in a second plane 224 other than the first plane 220 and optically coupled to the lasing disk 218. While the lasing disk 218 and guiding disk 222 are illustrated with substantially the same diameters, the lasing disk 218 and guiding disk 222 can have different diameters and different shapes in accordance with the present invention. The lasing disk 218 can be optically excited by suitable means such as optical pumping that provides pulsed light of an appropriate duty cycle or electrically excited with electrical current pulses of appropriate duty cycle as well known in the art.

The lasing disk 218 and the guiding disk 222 are optically coupled by resonant photon tunneling with the spacing apart of a selected distance using a material having a lower refractive index disposed between the lasing disk 218 and the guiding disk 222. More specifically, the lasing disk 218 and the guiding disk 222 are spaced apart with a pedestal 226 that is preferably comprised of a monocrystalline compound semiconductor material such as indium phosphide (InP). However, the lasing disk 218 and the guiding disk 222 can be suspended or otherwise spaced apart with a low refractive index material other than the monocrystalline compound semiconductor material (e.g., air, SiO.sub.2, or acrylic) to optically couple the lasing disk 218 and the guiding disk 222 by resonant photon tunneling. The lasing disk 218 is preferably connected to the monocrystalline perovskite oxide material 140 with a base pedestal 228 and the guiding disk 222 preferably includes a light output coupling 230 in the form of a circumferential V-shape or wedge-shaped notch as a light output coupling from the laser 216. However, the light output coupling can be provided with other configurations such as the output waveguide previously described in this detailed description of the drawings and also receive light with an input coupling as previously described in this detailed description of the drawings.

The laser 216 as previously described in this detailed description of the drawings can be formed with any number or techniques and processes such as molecular beam epitaxial growth of layers and then shaping the lasing disk 218, the guiding disk 222 layers, the pedestal 226 and the base pedestal 228 by multi-step photolithographic techniques and selective reactive ion etching techniques. For example, an initial In_{0.84}Ga_{0.16}As_{0.33}P_{0.67} etch stop layer is grown on the monocrystalline perovskite oxide material 140 and a 1.0 micron indium phosphide (InP) pedestal layer is grown on the etch stop layer. A 0.2 micron thick microcavity quantum well (MQW) layer is grown on the pedestal layer to form an active layer 154 as described with reference to FIG. 29. For example, the MQW layer comprises three (3) In_{0.53}Ga_{0.47}As quantum layers or wells each of approximate 100 Angstroms thickness disposed between In_{0.84}Ga_{0.16}As_{0.33}P_{0.67} barrier layers of approximate 100 Angstroms thickness with end caps having the barrier composition of approximate 700 Angstroms thickness. A second InP pedestal layer having a 0.65-micron thickness is subsequently grown on the MQW layer followed by a final passive layer of In_{0.84}Ga_{0.16}As_{0.33}P_{0.67} to a thickness of approximately 0.2 micron as the guiding disk layer. However, as can be appreciated by one of ordinary skill in the art, other suitable monocrystalline compound semiconductor materials can be used to fabricate the laser 216 such as those previously described in this detailed description of the drawings (e.g., InGaAs/InAlGaAs). As previously described in this detailed description of the drawings and as well known in the art, any number of techniques and process can be used to produce the structure of the laser 216, including multi-step photolithographic techniques.

The guiding disk 222 of the laser 216 preferably comprises a basically passive, absorption-less material at a different epitaxial level during layer growth for light guiding purposes. The photons generated in the lasing disk 218 leak into the guiding disk 222 via resonant waveguide coupling (i.e., resonant photon tunneling) through the pedestal 226. The coupling efficiency between the lasing disk 218 and the guiding disk 222 can be controlled by appropriately selecting the distance of separation between the two disks (218, 222). As the separation distance between the lasing disk 218 and the guiding disk 222 increases, the coupling efficiency decreases. The coupling length is the roundtrip length of the photons propagating around the circumference of the lasing disk 218 given approximately by πD, where D is the diameter of the disk. This double-microdisk structure enables the lasing disk 218 to provide a high Q value and low lasing threshold, while a light output coupling feature or structure can be provided on the guiding disk 222 to couple light out of the laser 216. By providing the light output coupling 230 on the guiding disk 222, the high Q value and low lasing threshold of the lasing disk is not adversely affected. The light output coupling 230 forms flat surfaces or windows (232, 234) through which light can be coupled out from the laser 216. Alternatively, the light output coupling 230 with the configuration as illustrated in FIG. 34, a grating, surface or opening having approximately a forty five (45) degree or other suitable angle can be formed on the upper axial end of the guiding disk 222 to provide a vertical component of lasing light emission from the guiding disk 222 of the laser 216 of the invention.

In the practice of the present invention, the estimated number of cavity modes with frequencies in the photoluminescence spectrum are less than two (single mode) if the diameter of the micromember is less than 5 microns and the spectral gain width of the quantum well is of the typical value of 60 nanometers. Microcavity outer diameters in the range of 2 microns to 5 microns are preferred to this end. However, the invention is not so limited and can be practiced using a lasing microcavity comprising one or more active quantum well (MQW) layers having a general circular cross-sectional periphery with a diameter up to 30 microns for example, such as from 10 to 30 microns, to provide an active optical medium that supports waveguiding optical modes, which include, but are not limited to, the whispering gallery mode. The invention also is not limited to the particular micromembers described and shown in the drawings and can be practiced using microdisk, microcylinder, microannulus (microring) and other shape micromembers so dimensioned as to provide an active optical medium that supports waveguiding optical modes.

Although certain active medium materials have been described in this detailed description of the drawings for purposes of illustration, other active medium materials may be considered for use as applied to other semiconductor structures in general and may be selected as possibly constrained by the designed wavelength of operation of the device, spectral width of emission, or fabrication process available. In addition, although the low refractive index materials and high refractive index materials are described as having particular refractive indices, those skilled in the art will recognize that they are used to indicate the typical refractive indices possessed by these materials. For example, within each material it is possible to have small refractive index fluctuations or variations spatially without affecting the mode confinement in the active lasing medium or the performance of the device. Furthermore, although the active lasing medium is shown with a rectangular cross-section, those skilled in the art will recognize that the core shape can deviate from a perfect rectangular shape with an averaged thickness and width dimensions of the invention and as set forth in the appended claims with regard to mode confinement and the performance of the device. Although the active layer is shown in the form of a layer with a width equal to the waveguide width, those skilled in the art will recognize that the specific shape and dimensions of the active layer can vary and the gain provided by the medium is dependent mainly on its volume of occupation being primarily at the center region of the cross-section of the waveguide core.

FIG. 35 illustrates a plan view of a semiconductor laser system 240 in accordance with an embodiment of the present invention. The semiconductor laser system 240 comprises a radiation source 242 having at least one microcavity semiconductor laser 244. However, the semiconductor laser system 240 can have any number of microcavity semiconductor lasers in accordance with the present invention. For example, the radiation source 242 can have a second microcavity semiconductor laser 246, a third microcavity semiconductor laser 248 and a fourth microcavity semiconductor laser 250. In addition, the radiation source 242 can have other semiconductor laser configurations in addition to a microcavity semiconductor laser configuration, such as a Vertical Cavity Surface Emitting Laser (VCSEL) (not shown) or an edge emitting laser (not shown).

The semiconductor laser system 240 also comprises at least one output waveguide 252 that is coupled and preferably optically coupled with evanescent wave coupling to the microcavity semiconductor laser 244 and preferably configured for coupling to at least one fiber optic cable 260. Preferably, the second microcavity semiconductor laser 246, third microcavity semiconductor laser 248 and fourth microcavity semiconductor laser 250 are also coupled and also preferably optically coupled with an evanescent wave coupling to a second output waveguide 254, a third output waveguide 256 and fourth output waveguide 258, respectively, and also preferably configured for coupling to an fiber optic cable, such as the second fiber optic cable 262, a third fiber optic cable 264 and a fourth optic cable 266. Spot size converter structures (not shown) can be used to adapt the small size of the waveguide mode to the larger size of the fiber mode. The semiconductor laser system 240 further comprises a laser control circuit 268 that is at least connected to the first microcavity semiconductor laser 244 and configured to at least control the operation of the first microcavity semiconductor laser 244. However the laser control circuit 268 can be configured to control the operation of the second microcavity semiconductor laser 246, third microcavity semiconductor 248 and/or fourth microcavity semiconductor laser 250 or a second control circuit (not shown), third control circuit (not shown) and/or a fourth control circuit (not shown) can be provided to control the second microcavity semiconductor laser 246, third microcavity semiconductor 248 and/or fourth microcavity semiconductor laser 250.

In accordance with the present invention, the semiconductor laser system 240 preferably comprises a semiconductor structure 134 as previously described with reference to FIGS. 24-29 and/or FIG. 34. Therefore, at least the first microcavity semiconductor laser 244 is preferably formed of the semiconductor structure 134 as previously discussed in this detailed description of the drawings with reference to FIGS. 24-29 and/or FIG. 34. Furthermore, the second microcavity semiconductor laser 246, third microcavity semiconductor laser 248, fourth microcavity semiconductor laser 250 and other microcavity semiconductor lasers of the semiconductor laser system 240 preferably comprise the semiconductor structure 134 as previously discussed in this detailed description of the drawings with reference to FIGS. 24-29 and/or FIG. 34.

More specifically, at least the first microcavity semiconductor laser 244 and preferably the second microcavity semiconductor laser 246, third microcavity semiconductor laser 248, fourth microcavity semiconductor laser 250 and other microcavity semiconductor lasers of the semiconductor laser system 240 are formed of a monocrystalline compound semiconductor material overlying the monocrystalline perovskite oxide material 140 that is overlying an amorphous oxide material 138, which is overlying the monocrystalline silicon substrate 136 as initially illustrated and described with reference to FIGS. 24-29 and/or FIG. 34. In addition, at least the first output waveguide 252 and preferably the second output waveguide 254, third output waveguide 256 and fourth output waveguide 258 are formed of a material, which is preferably a monocrystalline compound semiconductor material, overlying the monocrystalline perovskite oxide material.

The first output waveguide 252, second output waveguide 254, third output waveguide 256 and/or fourth output waveguide 258 can be coupled to the first semiconductor laser 244, second microcavity semiconductor laser 246, third microcavity semiconductor laser 248 and/or fourth microcavity semiconductor laser 250 as previously described with reference to FIGS. 30-33. However, in accordance with an embodiment of the present invention, the coupling of at least the first output waveguide 252 and the first microcavity semiconductor laser 244 is provided with the first output waveguide 252 overlying the first microcavity semiconductor laser 244. Furthermore, in accordance with another embodiment of the present invention, the coupling of the second output waveguide 254, third output waveguide 256, and fourth output waveguide 258 to the second microcavity semiconductor laser 246, third microcavity semiconductor laser 248 and fourth microcavity semiconductor laser 250 is provided with the second output waveguide 254 overlying the second microcavity semiconductor laser 246, the third output waveguide 256 overlying the third microcavity semiconductor laser 248 and the fourth output waveguide 258 overlying the fourth microcavity semiconductor laser 250.

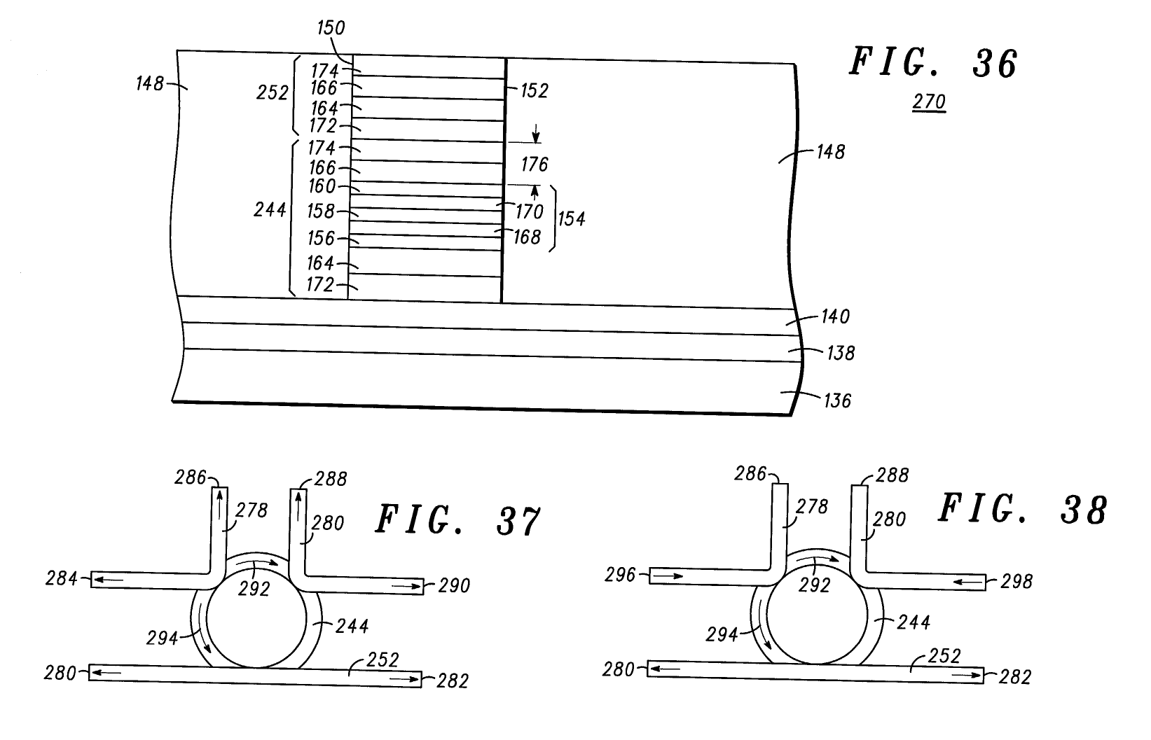

Referring to FIG. 36, a cross-sectional view of the semiconductor structure 270 comprising the first output waveguide 252 overlying the first microcavity semiconductor laser 244 taken along lines 36-36 of FIG. 35 is illustrated in accordance with the present invention. While FIG. 36 illustrates the cross-sectional view of the first output waveguide 252 overlying the first microcavity semiconductor laser 244, it should be understood that the cross-sectional view of FIG. 36 and the subsequent description is applicable to the second output waveguide 254 overlying the second microcavity semiconductor laser 246, the third output waveguide 256 overlying the third microcavity semiconductor laser 248 and/or the fourth output waveguide 258 overlying the fourth microcavity semiconductor laser 250. It should also be understood that the first microcavity semiconductor laser 244 can be formed and is preferably formed as described with reference to FIG. 29 as shown in FIG. 36 or as described with reference to FIG. 31 and the first output waveguide 252 can be and is preferably formed as described with reference to FIG. 31 and/or FIG. 34.

More specifically, and with continuing reference to FIG. 36, the semiconductor structure 270 comprises the monocrystalline silicon substrate 136, the amorphous oxide material 138 overlying the monocrystalline silicon substrate 136, the monocrystalline perovskite oxide material 140 overlying the amorphous oxide material 138 and the first monocrystalline compound semiconductor material overlying the monocrystalline perovskite oxide material 140. The first microcavity semiconductor laser 244 is formed at least partially of the first monocrystalline compound semiconductor material and the first output waveguide 252 is overlying the first microcavity semiconductor laser 244. The first output waveguide 252 is preferably formed at least partially of a second monocrystalline compound semiconductor material, which can be substantially similar to and preferably the same as the first monocrystalline semiconductor material or a monocrystalline compound semiconductor material other than the first monocrystalline compound semiconductor material.

In this illustrative embodiment of the present invention, the first microcavity semiconductor laser 244 comprises the first cladding layer 172, the first guiding layer 164 overlying the first cladding layer 172, the active layer 154 comprising barrier layers (168, 170) and quantum well layers (156, 158, 160) overlying the first guiding layer 164, the second guiding layer 166 overlying the active layer 154 and the second cladding layer 174 overlying the second guiding layer 166, which are substantially surrounded and preferably surround on the first lateral side 150 and the second lateral side 152 with the relatively low refractive index medium 148 as previously described in this detailed description of the drawings. The first output waveguide 252 comprises the first cladding layer 172, the first guiding layer 164 overlying the first cladding layer 172, the second guiding layer 166 overlying the first guiding layer 164 and the second cladding layer 174 overlying the second guiding layer as previously described with reference to FIG. 31.

Continuing with reference to FIG. 36, the first output waveguide 252 overlying the first microcavity semiconductor laser 244 is spaced a distance 176 from the active layer 154 to provide evanescent wave coupling between the first microcavity semiconductor laser 244 and the first output waveguide 252. More specifically, the second guiding layer 166 and the second cladding layer 174 provides the distance 176 from the active layer 154. However, other material layers can be provided to provide the distance 176 in accordance with the present invention.

The efficiency of the evanescent wave coupling between the first microcavity semiconductor laser 244 and the first output waveguide 252 can be controlled by the magnitude of the distance 176 that separates the first output waveguide 252 from the active layer 154. Generally, the efficiency of the evanescent wave coupling is inversely proportional to the magnitude of the distance 176. Therefore, as the distance 176 increases, the efficiency of the evanescent wave coupling decreases. The distance 176 for the first microcavity semiconductor laser 244 with the structure as previously described with reference to FIG. 29 is in the range of about 0.5 microns to about 4 microns depending on the material composition and index of the waveguide and the cladding layers as known in the art.

Referring to FIG. 37, the first microcavity semiconductor laser 244 can be coupled to the first output waveguide 252 with evanescent wave coupling at a segment of the first microcavity semiconductor laser 244. Alternatively, the first microcavity semiconductor laser can be coupled to multiple output waveguides with evanescent wave coupling at different segments of the first microcavity semiconductor laser 244. For example, the first microcavity semiconductor laser 244 can be coupled to the first output waveguide 252, a second output waveguide 278 and a third output waveguide 280 that are overlying the first microcavity semiconductor laser 244 at different segments of the first microcavity semiconductor laser 244, thereby providing multiple output ports such as the first output port 280, second output port 282, third output port 284, fourth output port 286, fifth output port 288 and sixth output port 290. As can be appreciated by one of ordinary skill in the art, the light in the first microcavity semiconductor laser 244 can be divided into multiple beams such as a first beam and a second beam with the first beam propagating in a first direction 292 (e.g., a clockwise direction) and the second beam propagating in a second direction 294 (e.g., a counterclockwise direction).

Referring to FIG. 38, one or more of the output waveguides (252, 278, 280) can also be configured to couple light from another light source or a second microcavity semiconductor laser (not shown) into the first microcavity semiconductor laser 244, thereby forming multiple input ports such as the first input port 296 and second input port 298. The input ports (296, 298) can be used to introduce light in the form of pulses or continuous wave beams into the first microcavity semiconductor laser 244, which can affect the properties of light output from the microcavity semiconductor laser 244. For example, the amplitudes, phases, frequencies, pulse duration, and polarization of the light output from the output ports (286, 288) can depend on the amplitudes, phases, frequencies, pulse duration, and polarization of the light input into one or more of the input ports (296, 298). The dependence can be different depending on the excitation level or population inversion in the first microcavity semiconductor laser 244, or on whether the input beams in the microcavity semiconductor laser are brought above or below the lasing thresholds. As can be appreciated by one of ordinary skill in the art, such an input-output dependence can be used for processing signals or information coded in the properties of the input light beams, and can be a useful device for application to optical communications, optical interconnects, optical sensing, optical signal processing, and optical computing. For example, the semiconductor structures having disk or ring lasers that are coupled to waveguides using evanescent coupling as described with reference to FIGS. 34-38 can be used as a part of an integrated electro-optical processing circuit that uses optics for “intra IC information communication” between functions, such as memory and processing functions, operating within one integrated circuit package, and can also be used as part of an “inter integrated circuit communication system” that uses optical data communications to transport information between a set of integrated electro-optical circuits, and as a part of an electro-optical network node that serves as a node in a local or wide area fiber optic network. As can also be appreciated by one of ordinary skill in the art, the presence of both input and output ports allows two or more microcavity semiconductor lasers to be connected by connecting the output port(s) of one microcavity semiconductor laser to the input port(s) of another microcavity semiconductor laser. As can be further appreciated by one of ordinary skill in the art, numerous microcavity semiconductor laser configurations can be provided in accordance with the present invention and numerous output coupling configurations can be provided in accordance with the present invention.

Clearly, these embodiments of integrated circuits having compound semiconductor portions and Group IV semiconductor portions are meant to illustrate what can be done and are not intended to be exhaustive of all possibilities or to limit what can be done. There is a multiplicity of other possible combinations and embodiments. For example, the compound semiconductor portion may include light emitting diodes, photodelectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., and optical laser), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections, which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well protected by circuitry to prevent harmful external signals from reaching the composite integrated circuit. A communications ground may be isolated from the ground signal in communications connections that use a ground communications signal.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is Claimed is:

1. A semiconductor structure, comprising:
a monocrystalline silicon substrate;
an amorphous oxide material overlying the monocrystalline silicon substrate;
a monocrystalline perovskite oxide material overlying the amorphous oxide material;
a first monocrystalline compound semiconductor material overlying the monocrystalline perovskite oxide material;
a microcavity semiconductor laser formed at least partially of said monocrystalline compound semiconductor material; and
a waveguide overlying said microcavity semiconductor laser.

2. The semiconductor structure of claim 1, wherein said waveguide overlying said microcavity semiconductor laser is optically coupled to said microcavity semiconductor laser.

3. The semiconductor structure of claim 1, wherein said waveguide overlying said microcavity semiconductor laser is optically coupled to said microcavity semiconductor laser with an evanescent wave coupling.

4. The semiconductor structure of claim 1, wherein said waveguide is formed at least partially from a second monocrystalline compound semiconductor material.

5. The semiconductor structure of claim 4, wherein said second monocrystalline compound semiconductor material is substantially the same as said first monocrystalline compound semiconductor material.

6. The semiconductor structure of claim 1, wherein said microcavity semiconductor laser comprises an elliptical cross-sectional periphery.

7. The semiconductor structure of claim 6, wherein said elliptical cross-sectional periphery comprises a circular cross-sectional periphery.

8. The semiconductor structure of claim 1, wherein said microcavity semiconductor laser comprises a microcavity semiconductor ring laser.

9. The semiconductor structure of claim 1, wherein said microcavity semiconductor laser comprises a microcavity semiconductor disk laser.

10. The semiconductor structure of claim 1, wherein said microcavity semiconductor laser comprises a distorted microcavity semiconductor ring laser.

11. The semiconductor structure of claim 1, wherein said microcavity semiconductor laser comprises a distorted microcavity semiconductor disk laser.

12. The semiconductor structure of claim 1, wherein said first monocrystalline compound semiconductor material forms an active lasing medium.

13. The semiconductor structure of claim 12, wherein said active lasing medium supports resonant modes having wavelengths compatible with a radial dimension of the microcavity semiconductor laser.

14. The semiconductor structure of claim 12, wherein said active lasing medium enables circulation of said plurality of photons about a periphery of said microcavity semiconductor laser in a manner capable of producing stimulated emission of radiation that generates a second plurality of photons capable of forming a lasing field within said active lasing medium.

15. The semiconductor structure of claim 12, wherein said active lasing medium comprises a relatively high refractive index medium that is substantially surrounded by a relatively low refractive index medium.

16. The semiconductor structure of claim 15, wherein said relatively high refractive index medium has a refractive index that is greater than approximately 2.5.

17. The semiconductor structure of claim 15, wherein said relatively low refractive index medium has a refractive index that is less than approximately 2.0.

18. The semiconductor structure of claim 15, wherein the ratio of the refractive indices of said relatively high refractive index medium and said relatively low refractive index medium is greater than approximately 1.3.

19. The semiconductor structure of claim 12, wherein said active lasing medium comprises a first cladding layer overlying said monocrystalline perovskite oxide material.

20. The semiconductor structure of claim 19, wherein said active lasing medium comprises an active layer overlying said first cladding layer.

21. The semiconductor structure of claim 12, wherein said active lasing medium comprises of an active layer.

22. The semiconductor structure of claim 21, wherein said active lasing medium comprises of a second cladding layer overlying said active layer.

23. The semiconductor structure of claim 21, wherein said active layer comprises a quantum well.

24. The semiconductor structure of claim 21, wherein said active layer comprises a plurality of quantum wells.

25. The semiconductor structure of claim 21, wherein said active layer comprises a quantum well barrier layer.

26. The semiconductor structure of claim 12, wherein said active lasing medium comprises a first cladding layer disposed between a first guiding layer and said monocrystalline perovskite oxide material.

27. The semiconductor structure of claim 26, wherein said active lasing medium comprises a second guiding layer disposed between an active layer and a second cladding layer.

28. The semiconductor structure of claim 1, wherein said monocrystalline compound semiconductor material comprises gallium arsenide (GaAs).

29. The semiconductor structure of claim 1, wherein said monocrystalline compound semiconductor material comprises indium phosphide (InP)

30. The semiconductor structure of claim 1, wherein said waveguide is coupled to said microcavity semiconductor laser with evanescent wave coupling at a segment of said microcavity semiconductor laser.

31. The semiconductor structure of claim 1, wherein said microcavity semiconductor laser comprises:
a first cladding layer overlying said monocrystalline perovskite oxide material;
a first guiding layer overlying said first cladding layer;
an active layer overlying said first guiding layer;
a second guiding layer overlying said active layer; and
a second cladding layer overlying said second guiding layer.

32. The semiconductor structure of claim 31, wherein said waveguide comprises a third cladding layer overlying said second cladding layer.

33. The semiconductor structure of claim 32, wherein said waveguide comprises a third guiding layer overlying said third cladding layer.

34. The semiconductor structure of claim 33, wherein said waveguide comprises a fourth guiding layer overlying said third guiding layer.

35. The semiconductor structure of claim 33, wherein said waveguide comprises a second active layer overlying said third guiding layer.

36. The semiconductor structure of claim 34, wherein said waveguide comprises a fourth cladding layer overlying said fourth guiding layer.

37. An electro-optical integrated circuit comprising the semiconductor structure of claim 1 for intra integrated circuit information communication.

38. An electro-optical integrated circuit comprising the semiconductor structure of claim 1 for inter integrated circuit information communication.

39. An electro-optic network node comprising the semiconductor structure of claim 1.

40. A semiconductor laser system, comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a plurality of microcavity semiconductor lasers formed at least partly from said monocrystalline compound semiconductor material;
a plurality of waveguides overlying said plurality of microcavity semiconductor lasers, said plurality of waveguides optically coupled to said plurality of semiconductor lasers with an evanescent wave coupling.

41. The semiconductor laser system of claim 40, further comprising a plurality of optic cables coupled to said plurality of waveguides.

42. The semiconductor laser system of claim 40, further comprising a control circuit connected to at least one of said plurality of microcavity semiconductor lasers and configured to control said at least one of said plurality of microcavity semiconductor lasers.

43. The semiconductor laser system of claim 42 further comprising a second control circuit.

44. An electro-optical integrated circuit comprising the semiconductor structure of claim 40 for inter integrated circuit information communication.

45. An electro-optic network node comprising the semiconductor structure of claim 40.
